(19) United States
(12) Patent Application Publication
(10) Pub. No.: US 2025/0060457 A1
(43) Pub. Date: Feb. 20, 2025

(54) SENSOR COVER, SENSOR SYSTEM, AND MOTOR VEHICLE

(71) Applicant: Volkswagen Aktiengesellschaft, Wolfsburg (DE)

(72) Inventor: Alexander Tietje, Wesendorf (DE)

(21) Appl. No.: 18/798,296

(22) Filed: Aug. 8, 2024

(30) Foreign Application Priority Data
Aug. 16, 2023 (DE) 102023207868.6

(51) Int. Cl. G01S 7/481; B06B 1/06; B08B 7/02; B60S 1/56; G01S 7/02

(52) U.S. Cl. CPC G01S 7/4813; B06B 1/0688; B08B 7/026; B60S 1/56; G01S 7/027

(57) ABSTRACT

A sensor cover for a sensor system configured to remove weather-induced soiling for the unimpaired use of a sensor within the sensor system is disclosed. The sensor cover includes at least one sensor section and at least one base body extending over the sensor. At least one electrode section is provided on the base body. The sensor cover includes at least one piezoactive actuator for generating sound waves in the sensor cover, with the piezoactive actuator arranged at the electrode section of the base body. Additionally disclosed is a sensor system incorporating the sensor cover and a motor vehicle equipped with the sensor system.

### RELATED APPLICATIONS

The present application claims priority to German Patent Application No. 10 2023 207 868.6, to Alexander Tietje, filed Aug. 16, 2023, the contents of which is incorporated by reference in its entirety herein.

### TECHNICAL FIELD

The present disclosure relates to a sensor cover for a sensor system designed to remove weather-induced soiling, ensuring the unimpaired use of a sensor within the system. It also pertains to the sensor system itself and its application in a motor vehicle.

### BACKGROUND

Within the scope of autonomous driving, the requirements for the sensors of necessary driver assistance systems increase as the degree of automation rises. These sensors are primarily installed at the front end of the vehicle, but also at the rear end, assuming an exposed position. Possible installation locations for the sensors include behind the brand emblem in the radiator grille, behind a panel in the bumper, or in the ventilation grille region. Weather conditions such as rain, ice formation, soiling, or salt adhesions, in particular, influence the reliability of these systems, which generally include interventions in the steering, braking, and acceleration behavior of an automobile, such as cruise control and adaptive cruise control.

The described conditions affect the transmission behavior of radomes for radiation of the electromagnetic spectrum. Radar sensors, in particular, can be limited in their functionality by supplying incorrect information or failing entirely. The consequences can be that obstacles or the surroundings, in general, are not recognized. Additionally, the perceived quality by the customer and the confidence in the safety of such an autonomously moving vehicle may suffer when driver assistance systems repeatedly fail.

Protective covers are known from the prior art. Various options for removing grime or icing on a protective cover are known. One method involves designing the protective cover so that dirt or water are removed by the flow or pressure of the wind; however, this method is highly dependent on the incident flow at the protective cover or the specific weather conditions. Another approach involves manipulating the surfaces to make it more difficult for water, ice, or dirt particles to adhere. While this measure complicates the adherence of dirt particles, it cannot completely prevent or eliminate icing. Introducing heat by installing heaters in the protective cover is another solution. These heaters may interact with the emitted or detected electromagnetic radiation of the sensors and are additionally very cost-intensive. Technologies based on the polarization of the electromagnetic field can only be conditionally used due to a filter effect of the wire netting, as metallic conductors like copper are used for heating so far.

A radome cleaning process is known from DE 10 2013 223 783 A1, which makes dirt more difficult to adhere and thus ice more difficult to develop by using an external ultrasonic transducer coupled to the radome, i.e., the cover of a sensor, to introduce ultrasonic frequency into the cover. However, this requires design measures to accommodate the ultrasonic transducer in the region of a radar and protect the sensor against environmental conditions.

### SUMMARY

It is an objective of the present disclosure to at least partially overcome some of the above-described disadvantages. Specifically, the goal is to provide simple and reliable de-icing and cleaning of a sensor cover.

Certain aspects are disclosed in the respective subject matter of the independent claims. Further implementations and preferred embodiments are detailed in the dependent claims. Features and details described in connection with the sensor cover according to this disclosure also apply to the sensor system and the motor vehicle described herein. Mutual reference is made to the individual aspects of the disclosure to ensure a comprehensive understanding.

A first example of the present disclosure is a sensor cover for a sensor system designed to remove weather-induced soiling, ensuring the unimpaired use of a sensor within the system. The sensor cover includes at least one sensor section and at least one base body extending over the sensor. It is equipped with at least one electrode section on the base body and at least one piezoactive actuator for generating sound waves in the sensor cover. The piezoactive actuator is arranged at the electrode section of the base body.

A second example of the present disclosure is a sensor system, particularly for a motor vehicle, which includes at least one sensor, at least one sensor cover according to the first example, at least one voltage source, and at least one sound transducer. The sensor cover is positioned so that its sensor section extends over the sensor, protecting it from environmental conditions. The voltage source and sound transducer are electronically connected to the electrode coatings to generate ultrasound.

This sensor system ensures that the sensor is protected from external conditions by means of the sensor cover. The voltage source and sound transducer can apply a frequency to the sensor covers to clean or de-ice the surface exposed to the weather. A control unit may be provided to control the ultrasonic frequency on the sensor cover or the electrode section of the sensor cover. The voltage source, such as an onboard electrical system, can modulate the voltage in terms of pulse length or frequency and amplitude. This allows deliberate control of the ultrasonic waves' power, as well as the frequency and amplitude of the mechanical vibrations generated at the interface between the adhesion and the sensor cover.

It may be advantageous for the voltage source and sound transducer to generate a frequency range in the ultrasonic range that differs from the frequency ranges of the covered sensor and other sensors arranged at a distance. This ensures that the ultrasound range required for cleaning does not influence the measurements conducted by the sensors located behind it or neighboring sensors. It is particularly advantageous to select an ultrasound range or frequency range not used by any of the installed sensors.

A third configuration of the present disclosure relates to a motor vehicle comprising at least one sensor system according to the second example. This configuration is particularly advantageous as it ensures the cleaning and de-icing of the sensors installed in the motor vehicle, thereby enhancing the safety of the driver assistance systems. Within the scope of the present disclosure, the sensor system may be a radar system and/or a LIDAR system. The sensor section is advantageously LIDAR-transparent or radar-transparent and ensures accurate distance measurement for the driver assistance system.

The advantages described in detail for the sensor cover in the first example apply similarly to the sensor system in the second example and the motor vehicle in the third configuration.

### BRIEF DESCRIPTION OF THE DRAWINGS

Additional advantages, features, and details of the present disclosure will be apparent from the following description, which describes in detail multiple exemplary embodiments with reference to the drawings. The features described in the claims and in the description can be essential to the present disclosure either alone or in any arbitrary combination. The present disclosure is shown in the following figures:

FIG. 1 is a schematic representation of a first sensor cover including an electrode section, according to some aspects of the present disclosure;

FIG. 2 is a schematic representation of the first sensor cover in a section A-A, according to some aspects of the present disclosure;

FIG. 3 is a schematic representation of a second sensor cover including two electrode sections, according to some aspects of the present disclosure;

FIG. 4 is a schematic representation of the second sensor cover in a section B-B, according to some aspects of the present disclosure;

FIG. 5 is a schematic representation of a sensor system, according to some aspects of the present disclosure; and

FIG. 6 is a schematic representation of a motor vehicle, according to some aspects of the present disclosure.

### DETAILED DESCRIPTION

As disclosed herein, a sensor section may be considered the region or section of the sensor cover that covers or extends over the functional region of the sensor. This section ensures that the sensor is protected against environmental conditions and can be used unimpaired.

In some examples, the sensor cover comprises a base body, on which at least one piezoactive actuator is arranged via at least one electrode section. As a result, the piezoactive actuator is operatively connected to the base body. The base body also includes the sensor section or a part of the sensor section of the sensor cover. The electrode section and the sensor section can overlap, be arranged next to one another, or have the same extension.

Ultrasound can be transmitted into the base body through the arrangement of the piezoactive actuator, allowing potential adhesions or soiling to be detached from the sensor cover by means of ultrasound. The ultrasound ensures that the adhesion of water drops, dirt particles, salt adhesions, and the nucleation of ice crystals is influenced by a suitable mode selection of the frequency range of the ultrasound and the attendant amplitude of the mechanical vibrations. This effect reduces the degree to which dirt adheres to the weather-exposed surface, making it difficult for ice to form. Additionally, heat can be generated directly in the coating or the piezoactive sensor cover to support thawing of ice on the outer surface.

Mechanical surface waves can be generated in the interface region or in the base body using the piezoactive actuator. The frequency is selected such that adhesions, ice, or similar substances undergo a phase change, such as melting or evaporation, due to the introduced energy. Alternatively, a suitable frequency or amplitude can be selected to induce forced vibration, ideally in the frequency range of the eigenmodes of the adhesions. Achieving resonance helps overcome cohesion forces within the adhering layers and adhesion forces at the interface between the adhesion and the outer surface of the sensor cover, effectuating the detachment of grime or ice. Additionally, the frequency can be selected to induce molecular friction processes within the piezoactive actuator or the surface, generating heat to support thawing.

Within the scope of the present disclosure, it may be advantageous for each piezoactive actuator to comprise a first electrode coating, a second electrode coating, and a piezoactive layer, where at least a section of the piezoactive layer is arranged between the first and second electrode coatings. This represents a particularly simple and cost-effective structure for a piezoactive actuator for the sensor cover. Due to the layer structure, the design is not influenced, and the low layer thicknesses can be easily incorporated into the design calculations. These layers can be applied quickly and easily to existing sensor covers, making them retrofittable. The layer structure eliminates the need for additional components to be introduced in the sensor region, simplifying the solution.

Using the electrode coating, the ultrasound frequency can be easily introduced into the piezoactive layer to clean the sensor cover, detaching soiling and icing from the outwardly directed surface. It is conceivable that the sensor section is sensor-transparent, ensuring that the measurements carried out by the sensor are unimpaired. For example, it ensures that the sensor cover's sensor section is suitable for radar or LIDAR measurements.

The electrode section may be provided on the base body either in a section or over the entire surface. If the electrode section runs in a section, it is advantageous for it to run along the sensor section, potentially surrounding the circumference of the sensor section. The first and second electrode layers can have the same progression as the electrode section, although the surfaces of the electrode layers and the electrode section may differ slightly. This facilitates the application of the electrode layers onto the base body, as a predefined surface exists for the electrode section. The surface of the piezoactive layer can correspond to the surface of the electrode section or the electrode layers.

If the sensor transparency of the coating is too low, the electrode material can be omitted on the coating, causing the excitation of vibrations to occur only in the edge region instead of across the entire surface of the piezoactive coating. Non-sensor-transparent materials can be used as electrodes in this case. If the piezoelectric layer itself has insufficient sensor transparency, it can be omitted in the trans-irradiated region, with sound waves transferred into the sensor section through structure-borne noise.

The piezoactive layer of each piezoactive actuator can have a thickness of 5 nm to 500 nm, preferably 10 nm to 250 nm, and more preferably 15 nm to 150 nm. This thickness ensures the transmission of ultrasonic frequency to remove soiling on the sensor cover's outer side. If multiple piezoactive layers are provided, they can each have different thicknesses. The thickness can vary over the cross-section of the piezoactive layer, ensuring effective transmission of ultrasound to the base body.

The piezoactive layer can be polyvinyl fluoride (PVDF), which is particularly suited for excitation by the electrode layers and is sensor-transparent. PVDF can be designed to be optically transparent, allowing high amplitudes at low voltage for effective ultrasound transfer. It is robust against physical, chemical, and mechanical effects, such as UV irradiation, oils, acids, bases, abrasion, and strikes. PVDF has the necessary physical properties for radar suitability, especially regarding attenuation and reflectivity, and exhibits superhydrophobic behavior, delaying ice formation and reducing ice adhesion.

The electrode coatings of each piezoactive actuator may include materials like indium tin oxide, fluoridated tin oxide, aluminum-doped tin oxide, or antimony tin oxide. These materials facilitate easy excitation of the piezoactive layer and can be easily applied to the base body or piezoactive layer material, making the sensor cover cost-effective and easy to manufacture.

It is conceivable that at least two piezoactive actuators are provided on each electrode section, with the ability to be separately modulated. Using multiple piezoactive actuators increases the introduced energy in the form of ultrasound, enhancing the reliability of the cleaning process. Different frequencies can be applied to introduce various waves into the base body material, ensuring and expediting the cleaning or de-icing process. Separate modulation of the actuators can generate constructive or destructive interference, promoting the elimination of adhesions and icing further. Additionally, a “direction” can be predefined for the adhesions or soiling, for example, downward.

Multiple cover layers can be provided, each comprising at least one base body and at least one piezoactive actuator. The sensor cover can be composed of various layers laminated together. Each cover layer is designed to cover the piezoactive actuator of the lower cover layer without forming an intermediate layer, ensuring sufficient adhesion of the coating on the base body or between the cover layers to prevent detachment due to introduced ultrasound.

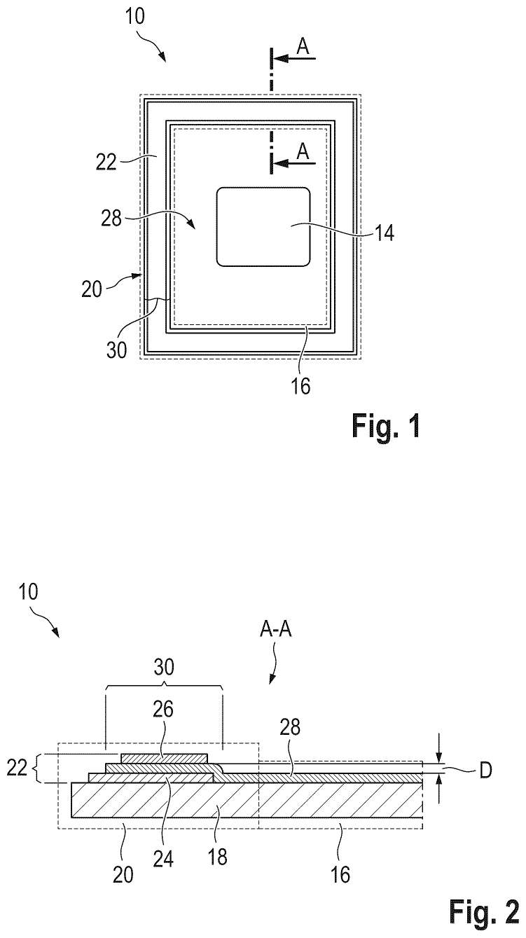

FIGS. 1 to 4 each show a top view and a sectional view of two different specific embodiments of a sensor cover 10 for a sensor system 12 for removing weather-induced soiling for the unimpaired use of a sensor 14 of the sensor system 12. The sensor cover 10 comprises at least one sensor section 16 and at least one base body 18 for extending over the sensor 14. This sensor section is sensor-transparent so as not to influence the mode of operation of the sensor 14 located behind it.

In a first example illustrated in FIGS. 1 and 2, at least one electrode section 20 extending around the sensor section 16 is provided on the base body 18. The provided piezoactive actuator 22 for generating sound waves in the sensor cover 10 is arranged at the at least one peripheral electrode section 20 of the base body 18.

For an easy generation of the sound waves, the piezoactive actuator 22 has a first electrode coating 24, a second electrode coating 26, and a piezoactive layer 28. At least a section 30 of the piezoactive layer 28 is arranged between the first electrode coating 24 and the second electrode coating 26.

As shown in FIG. 1, the base areas of the first electrode coating 24 and the second electrode coating 26 correspond to the size and the progression of the at least one electrode section 20. The first electrode coating 24 and the second electrode coating 26 of the piezoactive actuator 22 are made of indium tin oxide in the first exemplary embodiment.

However, the piezoactive layer 28 covers both the electrode section 20 and the sensor section 16. In this case, the piezoactive layer 22 is made of polyvinyl fluoride and has a thickness D of 5 nm to 50 nm in the at least one sensor section 16. In this way, the sensor transparency is ensured. This thickness D can also be 10 nm to 45 nm, and preferably 15 nm to 40 nm, to further increase the sensor transparency.

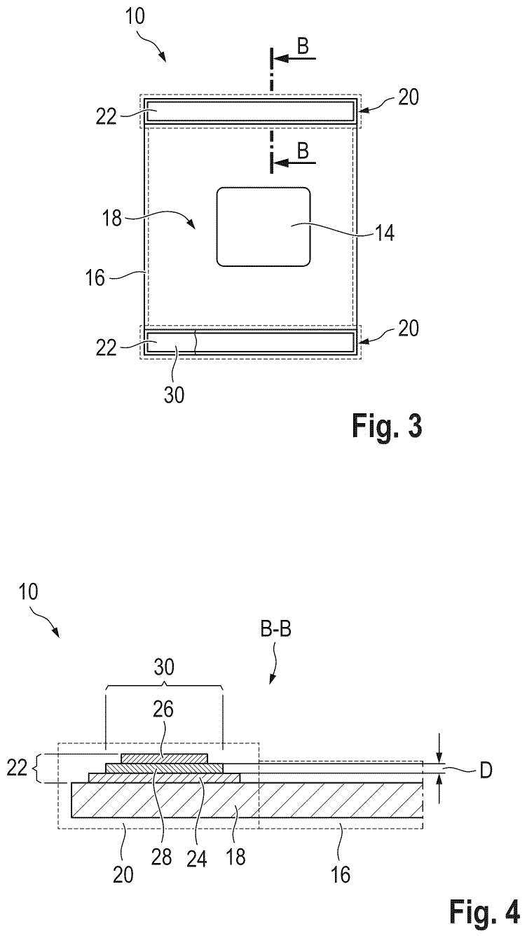

In a second example illustrated in FIGS. 3 and 4, two electrode sections 20 are provided on the base body 18 on opposing sides of the base body 18. The two electrode sections 20 thus have a sectional progression on the base body 18. They can be separately modulated so that they can introduce different frequencies into the sensor cover 10, for example, to predefine a direction for the soiling.

Since the piezoactive layer 22 here is only provided in the electrode sections 20 and between the first electrode layer 24 and the second electrode layer 26, sensor transparency of the piezoactive layer 28 does not necessarily have to be ensured. As a result, this layer can have a greater thickness D. It has proven useful for the piezoactive layer 28 in this embodiment to have a thickness D of 5 nm to 500 nm, preferably a thickness D of 10 nm to 250 nm, and more preferably 15 nm to 150 nm.

The piezoactive layer 28 is also polyvinyl fluoride in the second specific embodiment. However, the first electrode coating 24 of each piezoactive actuator 22 and the second electrode coating 26 of each piezoactive actuator 22 comprises fluoridated tin oxide. However, since two electrode sections 20 are provided, it is possible to use different materials for the first electrode layer 24 and the second electrode layer 26 per electrode section 20. This can be a combination of indium tin oxide and/or fluoridated tin oxide and/or aluminum-doped tin oxide and/or antimony tin oxide.

In one embodiment which is not shown, the specific embodiments of FIGS. 1 to 4 can be used as a cover layer in a layer structure that is made of multiple cover layers.

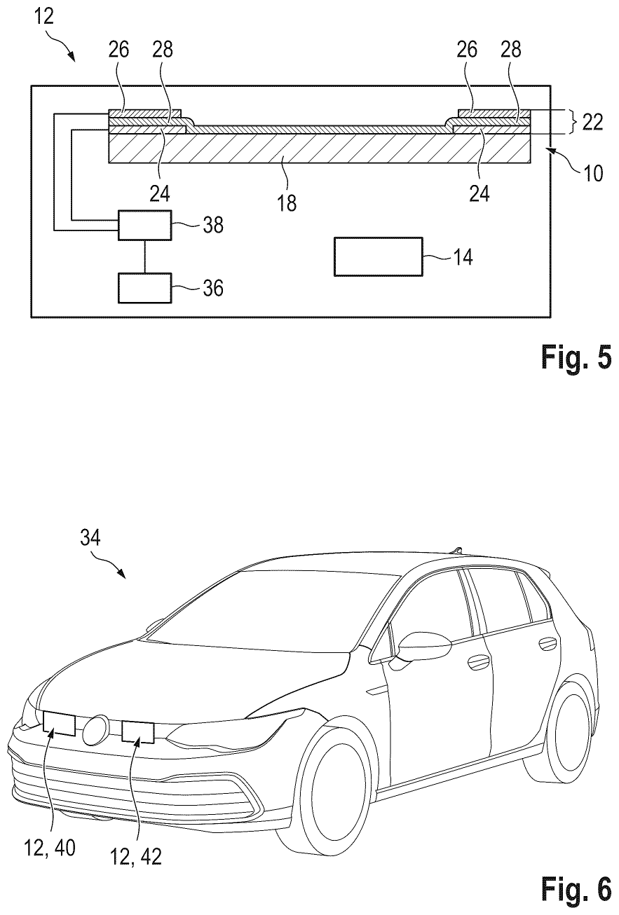

FIG. 5 shows a sensor system 12, in particular for a motor vehicle 34. The sensor system 12 comprises at least one sensor 14, at least one sensor cover 10 of the first specific embodiment, at least one voltage source 36, and at least one sound transducer 38. It is also possible for the sensor cover 10 to correspond to the second specific embodiment according to FIGS. 3 and 4.

The at least one sensor cover 10 is arranged so that the at least one sensor section 16 of the sensor cover 10 extends over the at least one sensor 14 and protects it against outside environmental conditions. In addition, the at least one voltage source 36 and the at least one sound transducer 38 are electronically connected to the at least one first electrode coating 24 and to the at least one second electrode coating 26 for generating ultrasound.

To prevent the installed sensors 14 from being influenced, the voltage source 36 and the sound transducer 38 are designed to generate a frequency range in the ultrasonic range, wherein the generated frequency range differs from the frequency ranges of the covered sensor 14 and/or sensors 14 that are arranged at a distance.

FIG. 6 shows a motor vehicle 34 comprising at least one sensor system 12 according to FIG. 5. In this case, a radar system 40 and a LIDAR system 42 are provided as the sensor system 12 in the motor vehicle, wherein the radar system 40 comprises a sensor cover according to FIGS. 1 and 2, and the LIDAR system 42 is equipped with a sensor cover according to FIGS. 3 and 4.

### LIST OF REFERENCE SIGNS

10 sensor cover
12 sensor system
14 sensor
16 sensor section
18 base body
20 electrode section
22 piezoactive actuator
24 first electrode coating
26 second electrode coating
28 piezoactive layer
30 section
34 motor vehicle
36 voltage source
38 sound transducer
40 radar system
42 LIDAR system
D thickness

1. A sensor cover for a sensor system configured to remove weather-induced soiling for the unimpaired use of a sensor of the sensor system, the sensor cover comprising:
at least one sensor section;
at least one base body configured to extend over the sensor;
at least one electrode section provided on the base body; and
at least one piezoactive actuator configured to generate sound waves in the sensor cover, the at least one piezoactive actuator being arranged at the at least one electrode section of the base body.

2. The sensor cover according to claim 1, wherein each piezoactive actuator comprises:
a first electrode coating;
a second electrode coating; and
a piezoactive layer, wherein at least a section of the piezoactive layer is arranged between the first electrode coating and the second electrode coating.

3. The sensor cover according to claim 1, wherein the at least one sensor section is sensor-transparent.

4. The sensor cover according to claim 1, wherein the at least one electrode section is provided on the base body in a section or over the entire surface.

5. The sensor cover according to claim 1, wherein the piezoactive layer of each piezoactive actuator has a thickness ranging from
5 nm to 500 nm, or
5 nm to 50 nm in the at least one sensor section.

6. The sensor cover according to claim 1, wherein the piezoactive layer is polyvinyl fluoride.

7. The sensor cover according to claim 1, wherein the first electrode coating and/or the second electrode coating of each piezoactive actuator comprises indium tin oxide, fluoridated tin oxide, aluminum-doped tin oxide, or antimony tin oxide.

8. The sensor cover according to claim 1, wherein the at least one electrode section comprises at least two electrode sections, and wherein each of the at least two electrode sections includes a respective piezoactive actuator, each of the respective piezoactive actuators configured to be separately modulatable.

9. The sensor cover according to claim 1, wherein the sensor cover comprises a plurality of cover layers, each cover layer including at least one base body and at least one piezoactive actuator.

10. A sensor system for a motor vehicle, comprising:
at least one sensor;
at least one sensor cover configured to remove soiling, the sensor cover comprising:
at least one sensor section,
at least one base body configured to extend over the at least one sensor,
at least one electrode section provided on the base body, and
at least one piezoactive actuator configured to generate sound waves in the sensor cover, the at least one piezoactive actuator being arranged at the at least one electrode section of the base body;
at least one voltage source; and
at least one sound transducer.

11. The sensor system according to claim 10, wherein each piezoactive actuator comprises:
a first electrode coating;
a second electrode coating; and
a piezoactive layer, wherein at least a section of the piezoactive layer is configured between the first electrode coating and the second electrode coating.

12. The sensor system according to claim 10, wherein the at least one sensor section is sensor-transparent.

13. The sensor system according to claim 10, wherein the at least one electrode section is configured on the base body in a section or over the entire surface.

14. The sensor system according to claim 10, wherein the piezoactive layer of each piezoactive actuator has a thickness ranging from 5 nm to 500 nm, or a thickness ranging from 5 nm to 50 nm in the at least one sensor section.

15. The sensor system according to claim 10, wherein the piezoactive layer is polyvinyl fluoride.

16. The sensor system according to claim 10, wherein the first electrode coating and/or the second electrode coating of each piezoactive actuator comprises indium tin oxide, fluoridated tin oxide, aluminum-doped tin oxide, or antimony tin oxide.

17. The sensor system according to claim 10, wherein the at least one electrode section comprises at least two electrode sections, and wherein each of the at least two electrode sections comprises a respective piezoactive actuator, each of the respective piezoactive actuators configured to be separately modulatable.

18. The sensor system according to claim 10, wherein the sensor cover comprises a plurality of cover layers, each cover layer comprising at least one base body and at least one piezoactive actuator.

19. A motor vehicle comprising:
at least one sensor system, the sensor system comprising:
at least one sensor, and at least one sensor cover configured to remove soiling, the sensor cover comprising:
at least one sensor section,
at least one base body configured to extend over the at least one sensor,
at least one electrode section provided on the base body, and
at least one piezoactive actuator configured to generate sound waves in the sensor cover, the at least one piezoactive actuator being arranged at the at least one electrode section of the base body;
at least one voltage source; and
at least one sound transducer.

20. The motor vehicle according to claim 19, wherein each piezoactive actuator comprises:
a first electrode coating;
a second electrode coating; and
a piezoactive layer, wherein at least a section of the piezoactive layer is arranged between the first electrode coating and the second electrode coating.
